(19) United States
(12) Patent Application Publication
(10) Pub. No.: US 2013/0277768 A1
(43) Pub. Date: Oct. 24, 2013

(54) Semiconductor Structure And Method For Manufacturing The Same

(71) Applicants: Haizhou Yin, Poughkeepsie, NY (US); Weize Yu, Beijing (CN)

(72) Inventors: Haizhou Yin, Poughkeepsie, NY (US); Weize Yu, Beijing (CN)

(21) Appl. No.: 13/816,228

(22) PCT Filed: Dec. 1, 2011
(86) PCT No.: PCT/CN11/83324

§ 371 Date: Feb. 9, 2013

(30) Foreign Application Priority Data
Oct. 11, 2011 (CN) 201110306885.4

(51) Int. Cl. H01L 29/66; H01L 29/78

(52) U.S. Cl. CPC H01L 29/66545; H01L 29/78
USPC 257/412; 438/294

(57) ABSTRACT

The present invention provides a semiconductor structure and a method for manufacturing the same. The method comprises the following steps: providing a substrate and forming a sacrificial gate, sidewall spacers and source/drain regions located on both sides of the sacrificial gate; forming an interlayer dielectric layer that covers the device; removing the sacrificial gate to form a cavity within the sidewall spacers; forming first oxygen absorbing layers in the cavity; forming a second oxygen absorbing layer in the remaining of the space of the cavity; and performing an annealing step to make the surface of the substrate form an interfacial layer. The present invention further provides a semiconductor structure. By forming a symmetrical interfacial layer in a channel region, the present invention has reduced processing difficulty while effectively mitigating short-channel effects and preserving carrier mobility.

The present application claims priority to Chinese Patent application No. 2011103068854, filed on Oct. 11, 2011, entitled “SEMICONDUCTOR STRUCTURE AND METHOD FOR MANUFACTURING THE SAME”, which is incorporated herein by reference in its entirety.

### FIELD OF THE INVENTION

The present invention relates to the field of semiconductor manufacturing, and particularity, to a semiconductor structure and a method for manufacturing the same.

### BACKGROUND OF THE INVENTION

With the developing of the semiconductor industry, the integrated circuits having more advanced performance and more powerful functions require greater component density. Size of each part and component, together with the space there between, will need to be further scaled down (Today, the dimensions of the components and space therebetween have already reached to nanometer scale). Therefore the demand for increasing density of components in a semiconductor device imposes more stringent requirements on the process control of the semiconductor device manufacturing.

The major reason why the further scaling down of the dimensions of metal oxide semiconductor (MOS) transistors is limited mainly lies in short-channel effects (SCE), which occur most often when the channel lengths are less than 0.1 micrometer. Failure of devices includes, but not limited to, Drain Induced Barrier Lowering (DIBL, i.e. low source/drain breakdown voltage), sub-threshold leakage, and instability of thresholds, etc. These problems are generally referred to as short-channel effects, and are mainly related to Equivalent Oxide Thickness (EOT) of interfacial layers.

In order to improve current transmitting capacity of devices, it is necessary to reduce Equivalent Oxide Thickness, which, however, will lead to decrease in carrier mobility. In the prior art, asymmetrical EOT design is used. That is, EOT is designed to be thicker at source and thinner at drain. Such a structure can effectively avoid reduction of carrier mobility and improve current transmitting capacity of devices as well. However, manufacturing of an unsymmetrical EOT requires complicated processes, and the circuit layout designs for an unsymmetrical EOT are also difficult.

Therefore, it is desirable to provide a semiconductor structure having a symmetrical EOT and a method for making such a structure, which can simplify the current semiconductor manufacturing processes.

### SUMMARY OF THE INVENTION

The present invention is aimed to provide a semiconductor structure and a method of manufacturing such a structure, which can effectively reduce difficulties in the manufacturing process and, at the same time, substantially preserve the device performances.

In accordance with one aspect of the present invention, a method for manufacturing a semiconductor structure, comprising:
(a) providing a substrate (100) and forming, on the substrate (100), a sacrificial gate, sidewall spacers and source/drain regions (110) located on both sides of the sacrificial gate;
(b) forming an interlayer dielectric layer (240) to cover the source/drain regions (110), the sacrificial gate and the sidewall spacers;
(c) removing the sacrificial gate to form a cavity within the sidewall spacers;
(d) forming first oxygen absorbing layers (250) to be in contact with interior walls of the sidewall spacers in the cavity;
(e) forming a second oxygen absorbing layer (260) in the remaining space of the cavity, wherein the oxygen absorbing capacities of the first oxygen absorbing layers (250) is less than that of the second oxygen absorbing layer (260); and
(f) performing an annealing step so that an interfacial layer is formed on the surface of the substrate (100).

In accordance with another aspect of the present invention, a semiconductor structure is disclosed, which comprises a substrate (100), source/drain regions (110), a gate stack and an interfacial layer, wherein

the substrate (100) has a channel region;

the source/drain regions (110) are formed in the substrate (100) and located on both sides of the channel region;

the gate stack comprises a high-k dielectric layer (210) and a gate on the high-k dielectric layer; the high-k dielectric layer (210) is located on the channel region; and wherein the gate comprises first oxygen absorbing layers (250) and a second oxygen absorbing layer (260); the first oxygen absorbing layers (250) are formed to surround sidewalls of the second oxygen absorbing layer (260); and the oxygen absorbing capacity of the first oxygen absorbing layer (250) is less than that of the second oxygen absorbing layer (260);

the interfacial layer is located under the high-k dielectric layer (210) and consists of first interfacial layers (120) and a second interfacial layer (130); the first interfacial layers (120) are located near the source and the drain of the source/drain regions (110), respectively; the second interfacial layer (130) is located between the first interfacial layers (120), and the thickness of the first interfacial layers (120) is greater than that of the second interfacial layer (130).

Compared to the semiconductor structure in the prior art, which have a thick EOT at the source and a thin EOT at the drain, the semiconductor structure in the present invention, having a symmetrical layout, together with the method for manufacturing such a structure, disclosed herein below, exhibit the following advantages.

The semiconductor structure in the present invention includes different layers with various oxygen absorption capacities. Because of the differences in oxygen absorbing capacities between different oxygen absorbing layers, a thick EOT is formed at the interfaces adjacent to source/drain regions and a thin EOT is formed in the central portion of the same interfacial layer. Studies have shown that devices with EOT in symmetrical arrangement, disclosed in the present invention, can achieve an equivalent or higher electrical current transmitting capacity than the traditional devices with asymmetrical EOT arrangement while still preserving the carrier mobility. In addition, it is known that the manufacturing process of asymmetrical EOT is complicated, and circuit layout designs are not easy, whereas making a device with a symmetrical EOT requires fewer steps and a less complicated fabrication process. Therefore, the semiconductor structure and the method of manufacturing disclosed in the present invention can preserve the electrical current transmitting capacity of devices without jeopardizing the carrier mobility, while effectively cutting down the complexity of device manufacturing processes overall and offering fewer fabrication steps.

### BRIEF DESCRIPTION OF THE DRAWINGS

Other characteristics, purposes and advantages of the present invention are made more evident according to the following detailed description of exemplary embodiment(s) in conjunction with the accompanying drawings.

FIG. 1 illustrates a flowchart of an exemplary method for manufacturing a semiconductor structure according to an embodiment of the present invention; and

FIG. 2˜FIG. 8 diagrammatically illustrate cross-sectional views of an exemplary semiconductor structure at respective stages of an exemplary manufacturing process in accordance with various aspects of the present invention and the flowchart shown in FIG. 1.

The same or similar reference signs in the accompanying drawings denote the same or similar elements, parts and components.

### DETAILED DESCRIPTION OF THE INVENTION

The purpose, advantages and the technical solution provided by the present invention are made more evident in the following detailed description of exemplary embodiments, in conjunction with accompanying drawings.

Embodiments of the present invention are described in detail below, wherein examples of the embodiments are illustrated in the drawings, in which the same or similar reference signs throughout denote the same or similar elements, parts and components, or elements, parts, and components have the same or similar functions. It should be appreciated that the embodiments described below in conjunction with the drawings are illustrative, and are provided for explaining the present invention only, thus shall not be interpreted as limitations to the present invention.

Various embodiments or examples are provided hereafter to implement different structures of the present invention. To simplify the disclosure of the present invention, description of components and arrangements of specific examples are given below. Of course, they are only illustrative, and are not limiting the present invention. Moreover, in the present invention, reference numbers and/or letters may be repeated in different embodiments. Such repetition is for purposes of simplification and clarification, yet does not denote any relationship between respective embodiments and/or arrangements being discussed. Furthermore, the present invention provides various examples for various processes and materials. However, it is obvious for a person of ordinary skill in the art that other processes and/or materials may alternatively be utilized. In addition, the following structure in which a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. It should be noted that the component(s) illustrated in the drawings may not be drawn to scale. Description of conventional components, processing technologies and fabrication techniques are omitted herein in order not to un-intentionally and unnecessarily limit the scope of the present invention.

The semiconductor structure disclosed in the present invention includes several preferred structures. One of the preferred structures is described herein below in detail.

### First Embodiment

Referring to FIG. 8, FIG. 8 illustrates a cross-sectional view of a semiconductor structure in accordance with the aspects of the present invention. The semiconductor structure comprises a substrate 100, source/drain regions 110, a gate stack and an interfacial layer, wherein

the substrate 100 has a channel region;

the source/drain regions 110 are formed in the substrate 100 and located on both sides of the channel region;

the gate stack comprises a high-k dielectric layer 210 and a gate located on the high-k dielectric layer 210; the high-k dielectric layer 210 is located on the channel region; wherein, the gate comprises first oxygen absorbing layers 250 and a second oxygen absorbing layer 260; the first oxygen absorbing layers 250 are formed to surround the sidewalls of the second oxygen absorbing layer 260, and the oxygen absorbing capacities of the first oxygen absorbing layers 250 is less than that of the second oxygen absorbing layer 260.

An interfacial layer is located under the high-k dielectric layer 210 and consists of first interfacial layers 120 and a second interfacial layer 130; the first interfacial layers 120 are located near the source and the drain of the source/drain regions 110, respectively; the second interfacial layer 130 is located between the first interfacial layers 120, and the thickness of the first interfacial layers 120 is greater than that of the second interfacial layer 130.

Since the thickness of the first interfacial layers 120 is greater than that of the second interfacial layer 130, a symmetrical structure which is thicker at its two ends and thinner in the middle is formed. The length of the second interfacial layer 130, i.e., the thinner portion, is greater than 80% of the whole interfacial layer, and the remaining 20% is the first interfacial layers 120, i.e. the thicker portions, which occupy 10% near the source and 10% near the drain, respectively.

Aforesaid first oxygen absorbing layers 250 and the second oxygen absorbing layer 260 can absorb oxygen, which may reduce equivalent oxide thickness (EOT) of the interfacial layers underneath by absorbing more oxygen. The oxygen absorbing capacities of the first oxygen absorbing layers 250 and the second oxygen absorbing layer 260 are different, which will in turn form the first interfacial layers 120 and the second interfacial layer 130 with different equivalent oxide thicknesses. The thickness of the second interfacial layer 130 is greater than the thickness of the first interfacial layers 120. The interfacial layers of different thicknesses can effectively control the short-channel effects of semiconductor devices and maintain the carrier mobility at the same time.

The material for the high-k dielectric layer 210 may, for example, be a material selected from a group consisting of HfAlON, HfSiAlON, HfTaAlON, HfTiAlON, HfON, HfSiON, HfTaON and HfTiON, or combinations thereof. The thickness of the high-k dielectric layer 210 may be about 1 nm-10 nm, for example, 1 nm, 5 nm or 10 nm.

Both the first oxygen absorbing layers 250 and the second oxygen absorbing layer 260 may be selected from Ti, Hf, Ta, W and/or nitrides thereof, as long as the oxygen absorbing capacities of the first oxygen absorbing layers 250 are less than that of the second oxygen absorbing layer 260.

Optionally, before forming the first oxygen absorbing layers 250 and the second oxygen absorbing layer 260, a work function metal layer is formed on the high-K dielectric layer 210 to adjust the threshold voltage of the device. The metal layer may be metals such as Ti, Ta, Al and/or other nitrides, for example, MN, TaAlN, etc.

The preferred embodiment is further described below in conjunction with the method for manufacturing a semiconductor device disclosed in the present invention.

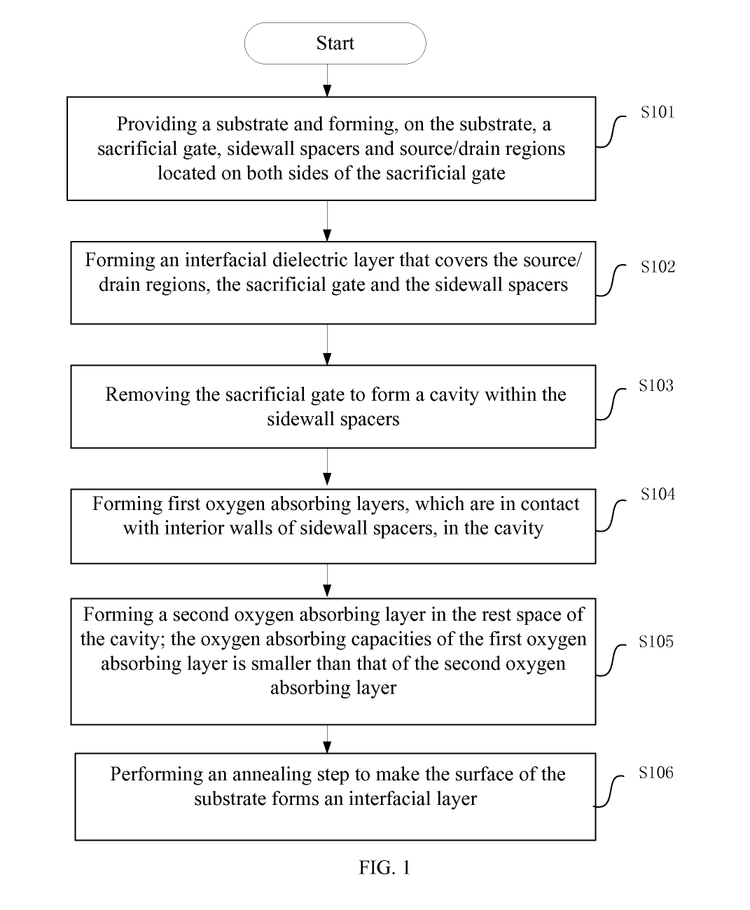

Referring to FIG. 1, a flowchart of an exemplary method for manufacturing a semiconductor structure, according to an exemplary embodiment of the present invention, is disclosed, and the method comprises the following steps.

At step S101, a substrate 100 is provided, and source/drain regions 110, a sacrificial gate, and sidewall spacers and source/drain regions on both sides of the sacrificial gate are formed on the substrate 100; the sacrificial gate comprises a high-k dielectric layer 210, a poly-Si gate 220, and a mask layer 230 (or referred to as a cap layer) covering the poly-Si gate; the mask layer 230 may be optionally present in other embodiments of the present invention;

At step S102, an interlayer dielectric layer 240 is formed to cover the source/drain regions 110, the mask layer 230 and the sidewall spacers;

At step S103, the sacrificial gate is removed to form a cavity within the sidewall spacers;

At step S104, first oxygen absorbing layers are formed to be in contact with the interior walls of the sidewall spacers in the cavity;

At step S105, a second oxygen absorbing layer 260 is formed in the remaining space of the cavity; the oxygen absorbing capacities of the first oxygen absorbing layers 250 are less than that of the second oxygen absorbing layer;

At step S106, an annealing is performed so that the surface of the substrate 100 forms an interfacial layer.

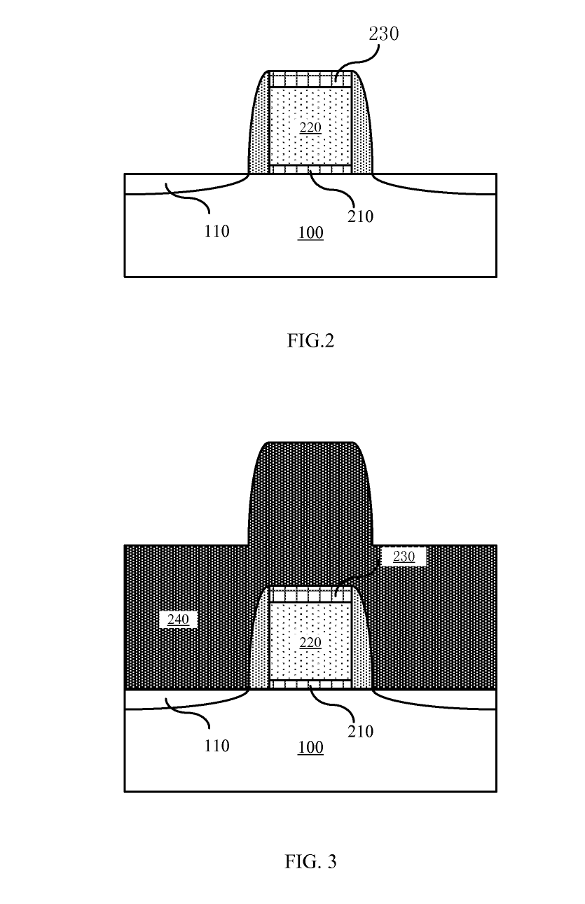

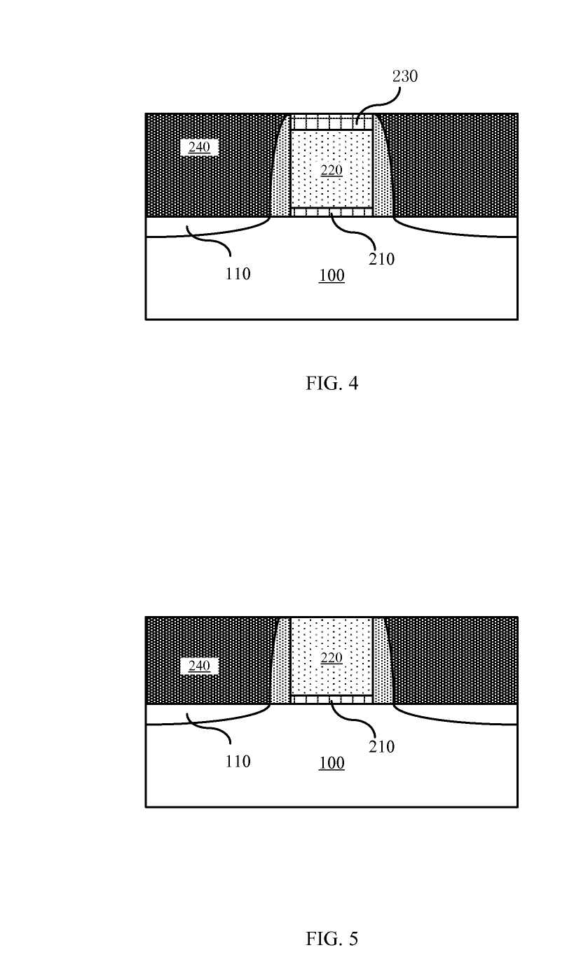

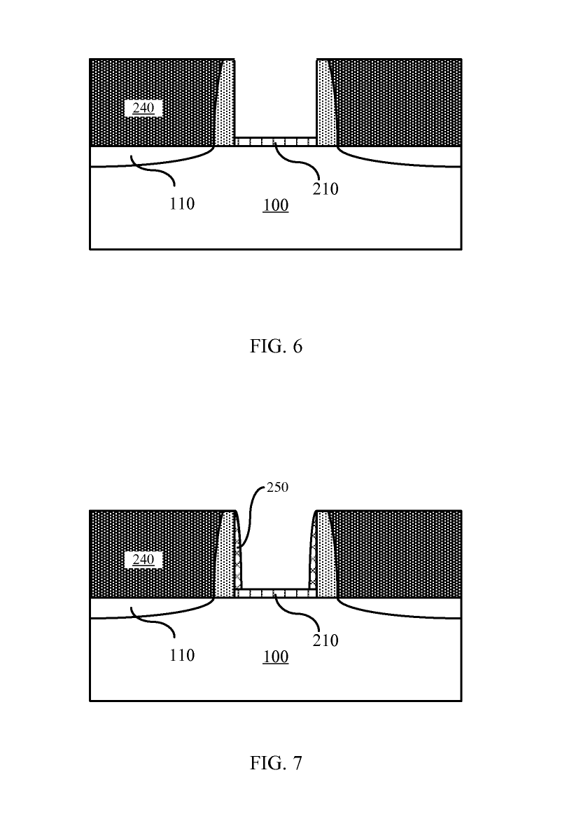

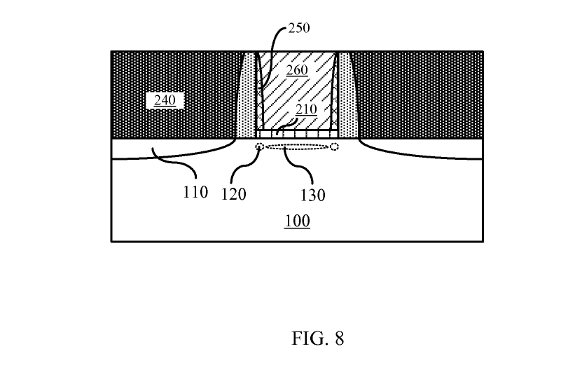

Steps S101 through S106 are described herein below in conjunction with FIG. 2 to FIG. 8, which illustrate cross-sectional views of an exemplary semiconductor structure at respective stages of the manufacturing process according to the flowchart shown in FIG. 1, in accordance with the various embodiments of the present invention. It should be noted that the drawings for respective embodiments are for illustration purpose only, and therefore are not necessarily drawn to scale.

At step S101, a substrate 100 is provided. As shown in FIG. 2, the substrate 100 may be a silicon substrate (e.g. a silicon wafer). According to design requirements in the prior art (e.g. a P-type substrate or an N-type substrate), the substrate 100 may be of various doping configurations. The substrate 100 in other embodiments may further include other basic semiconductors, for example, germanium. Alternatively, the substrate 100 may comprise a compound semiconductor, such as SiC, GaAs, InAs or InP. Typically, the substrate 100 may have, but not limited to, a thickness of about several hundred micrometers, which, for example, may be in the range of 400 μm-800 μm.

In one example of the present invention, a high-k dielectric material is formed on the substrate 100. The high-k dielectric material may be a material selected from a group consisting of HfAlON, HfSiAlON, HfTaAlON, HfTiAlON, HfON, HfSiON, HfTaON and HfTiON, or combinations thereof. The thickness of the high-k dielectric material may be about 2 nm˜10 nm, for example, 5 nm or 8 nm. The high-k dielectric material may be formed by thermal oxidization, Chemical Vapor Deposition (CVD), Atom Layer Deposition (ALD) or a similar technique. In other instances of the present invention, a conventional dielectric layer may be firstly formed and then removed together with the sacrificial gate in the subsequent process.

In another example of the present invention, a poly-Si material is deposited on the high-k dielectric material. A poly-Si layer may be formed by Chemical Vapor Deposition or a similar technique.

In yet another example of the present invention, a mask layer covering the poly-Si gate is formed. In other examples of the present invention, formation of the mask layer is optional. When the mask layer is formed, the materials in the mask layer, the poly-Si material and the gate dielectric material are etched with a gate pattern as a mask to form a sacrificial gate. The sacrificial gate may comprise the high-k gate dielectric layer 210, the poly-Si gate 220 and the mask layer 230. However, the present invention is not limited to aforesaid examples. Instead, the gate dielectric material may not be etched at this step in other examples of the present invention. In cases when the gate dielectric materials are not etched away, the sacrificial gates may comprise the poly-Si gate 220 and the mask layer 230.

The mask layer may be formed with a material selected from a group consisting of Si₃N₄, SiO₂, Si₂N₂O and SiC, or combinations thereof, and/or other material as appropriate.

In still another example of the present invention, source and drain extension implantation and halo implantation may be implemented so as to form source and drain extension regions and a halo implantation region.

Sidewall spacers are formed to surround the sacrificial gate.

The source/drain regions 110 may be formed by means of implanting P-type or N-type dopants or impurities into the substrate 100. For example, for PMOS, the source/drain regions 110 may be P-type doped, whereas for NMOS, the source/drain regions 110 may be N-type doped. The source/drain regions 110 may be formed by methods including lithography, ion implantation, diffusion and/or other process as appropriate. In the present examples, the source/drain regions 110 are located in the substrate 100. In other examples, the source/drain regions 110 may be raised source/drain structures formed by a selective epitaxial growth method, wherein the top of the epitaxial portions are higher than the bottom of the gate stack (the expression “the bottom of the gate stack” herein refers to the interface between the gate stack and the semiconductor substrate 100).

At step S102, an interfacial dielectric layer 240 is formed to cover the source/drain regions 110, the sacrificial gate and the sidewall spacers. As shown in FIG. 3, the interfacial dielectric layer 240 may be formed on the substrate 100 by means of CVD, high-density plasma CVD, spin coating or other method as appropriate. The material for the interlayer dielectric layer 240 may be a material selected from a group consisting of SiO₂, carbon doped SiO₂, BPSG, PSG, UGS, Si₂N₂O, and a low-k material, or combinations thereof. The thickness of the interfacial dielectric layer 240 may be in the range of 40 nm-150 nm, for example, 80 nm, 100 nm or 120 nm.

At step S103, the sacrificial gate is removed to form a cavity within the sidewall spacers. At first, the interfacial dielectric layer 240 is removed by a planarization process, which stops on top of the mask layer 230, as shown in FIG. 4. The planarization process is performed to expose top of the mask layer 230 so that the mask layer 230 is flushed with the interlayer dielectric layer 240 (herein, the term “flushed with” means that the difference between the heights of two portions is in the range of processing tolerance).

Next, the mask layer 230 is removed, which is stopped on the top of the poly-Si gate 220, as shown in FIG. 5. The planarization process is performed so that the top layer of the poly-Si gate 220 is exposed and is flushed with the interfacial dielectric layer 240.

Then, the poly-Si gate 220 is removed to form a cavity. The poly-Si gate 220 is removed by etching, so as to expose the high-k dielectric layer 210, as shown in FIG. 6. In other examples of the present invention, the high-k dielectric layer 210 may also be removed together, and subsequently a new high-k dielectric layer 210 is formed. If a conventional gate dielectric layer has been formed in the foregoing steps, the gate dielectric layer may also be removed together at this step, and a new high-k dielectric layer is formed afterwards.

At step S104, first oxygen absorbing layers 250, which are symmetrical and are in contact with the sidewall spacers, are formed in the cavity, as shown in FIG. 7. An oxygen absorbing material is formed in the cavity on the high-k dielectric layer 210 by deposition. Then the first oxygen absorbing layers 250 are formed on both sides of the cavity that are in contact with the source/drain regions 110 by anisotropic etching. The material for the first oxygen absorbing layers 250 may be Ti, Hf, Ta, W and/or nitrides thereof.

At step S105, a second oxygen absorbing layer 260 is formed in the remaining of the space of the cavity. Referring to FIG. 8, a material for the second oxygen-absorbing layer 260 is deposited in the remaining of the space of the cavity and then is planarized, so that the second oxygen absorbing layer 260 is flushed with the upper surface of the interfacial dielectric layer 240. The material for the second oxygen absorbing layer 260 may be Ti, Hf, Ta, W and/or nitrides thereof. It should be noted that the selection for the first oxygen absorbing layers 250 and the second oxygen absorbing layer 260 needs to satisfy the requirement that the oxygen absorbing capacities of the first oxygen absorbing layers 250 are less than that of the second oxygen absorbing layer 260.

The first oxygen absorbing layers 250 and the second oxygen absorbing layer 260 will absorb oxygen so as to reduce the equivalent oxide thickness of the interfacial layer underneath by absorbing more oxygen. The oxygen absorbing rate of the material for the second oxygen absorbing layer 260 is greater than that of the material for the first oxygen absorbing layers 250.

At step S106, annealing is performed so that the surface of the substrate 100 forms an interfacial layer. The interfacial layer consists of first interfacial layers 120 and a second interfacial layer 130, which have different equivalent oxide thicknesses. The thickness of the second interfacial layer 130 is smaller than that of the first interfacial layers 120. The interfacial layers of different thicknesses are favorable for alleviating short-channel effects of the devices, and effectively avoiding reduction of carrier mobility as well.

The length of the second interfacial layer 130 occupies more than 80% of the whole interfacial layer, whereas the remaining 20% is the combination of the length of the first interfacial layers 120 (i.e., the thicker portions), which occupies 10% near the source region and 10% near the drain region, respectively.

In summary, EOT in symmetrical arrangement can be designed and fabricated by a simplified process demonstrated and employed in the semiconductor structure and the method of manufacturing the same structure, which are disclosed in the present invention. Studies have shown that, compared to using EOT in asymmetrical layout employed in traditional semiconductors, EOT in symmetrical layout can achieve very good device performances, for example, current transmission capacity, carrier mobility etc., and considerably simplify the processes and steps of making the same.

Although the exemplary embodiments and their advantages have been described in detail, it should be understood that various alterations, substitutions and modifications may be made to the embodiments without departing from the spirit of the present invention and the scope as defined by the appended claims. For other examples, it may be easily recognized by a person of ordinary skill in the art that the order of processing steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

What is claimed is:

1. A method for manufacturing a semiconductor structure, comprising:
(a) providing a substrate (100) and forming, on the substrate (100), a sacrificial gate, sidewall spacers and source/drain regions (110) located on both sides of the sacrificial gate;
(b) forming an interlayer dielectric layer (240) to cover the source/drain regions (110), the sacrificial gate and the sidewall spacers;
(c) removing the sacrificial gate to form a cavity within the sidewall spacers;
(d) forming first oxygen absorbing layers (250) to be in contact with interior walls of the sidewall spacers in the cavity;
(e) forming a second oxygen absorbing layer (260) in the remaining space of the cavity, wherein the oxygen absorbing capacities of the first oxygen absorbing layers (250) is less than that of the second oxygen absorbing layer (260); and
(f) performing an annealing step so that an interfacial layer is formed on the surface of the substrate (100).

2. The method of claim 1, wherein in the direction of the sacrificial gate length, the length of the second oxygen absorbing layer (260) is greater than 80% of the length of the sacrificial gate.

3. The method of claim 1, wherein the first oxygen absorbing layer (250) is Ti, Hf, Ta, W and/or nitrides thereof.

4. The method of claim 1, wherein the second oxygen absorbing layer (260) is Ti, Hf, Ta, W and/or nitrides thereof.

5. The method of claim 1, wherein in a case where the sacrificial gate comprises a gate dielectric and a poly-Si gate, the method further comprises forming the cavity by removing the poly-Si gate.

6. The method of claim 1, wherein the interfacial layer comprises first interfacial layers and a second interfacial layer;
the first interfacial layers are located under the first oxygen absorbing layers (250), and the second interfacial layer is located under the second oxygen absorbing layer (260); and
the length of the second interfacial layer is greater than 80% of the length of the sacrificial gate.

7. The method of claim 1, wherein the step (c) comprises:
planarizing the interlayer dielectric layer (240) till the top of the sacrificial gate is exposed, and etching the sacrificial gate to form the cavity.

8. The method of claim 7, wherein after formation of the cavity, the method further comprises:
forming a gate dielectric layer at bottom of the cavity.

9. A semiconductor structure comprising a substrate (100), source/drain regions (110), a gate stack and an interfacial layer, wherein
the substrate (100) has a channel region;
the source/drain regions (110) are formed in the substrate (100) and located on both sides of the channel region;
the gate stack comprises a high-k dielectric layer (210) and a gate on the high-k dielectric layer; the high-k dielectric layer (210) is located on the channel region;
and wherein the gate comprises first oxygen absorbing layers (250) and a second oxygen absorbing layer (260); the first oxygen absorbing layers (250) are formed to surround sidewalls of the second oxygen absorbing layer (260); and the oxygen absorbing capacity of the first oxygen absorbing layer (250) is less than that of the second oxygen absorbing layer (260); and
the interfacial layer is located under the high-k dielectric layer (210) and consists of first interfacial layers (120) and a second interfacial layer (130); the first interfacial layers (120) are located near the source and the drain of the source/drain regions (110), respectively; the second interfacial layer (130) is located between the first interfacial layers (120), and the thickness of the first interfacial layers (120) is greater than that of the second interfacial layer (130).

10. The semiconductor structure of claim 9, wherein in the direction of the gate length, the length of the second interfacial layer (130) is greater than 80% of the length of the gate.

11. The semiconductor structure of claim 9, wherein the length of the second interfacial layer (130) is greater than 80% of the length of the whole interfacial layer, and the remaining thereof is the first interfacial layers (120).

12. The semiconductor structure of claim 9, wherein the thickness of the first interfacial layers (120) is greater than 0.5 nm, and the thickness of the second interfacial layer (130) is less than 0.5 nm.

13. The semiconductor structure of claim 9, wherein the gate is made of an oxygen absorbing material.

14. The semiconductor structure of claim 9, wherein the first oxygen absorbing layer (250) is Ti, Hf, Ta, W and/or nitrides thereof.

15. The semiconductor structure of claim 9, wherein the second oxygen absorbing layer (260) Ti, Hf, Ta, W and/or nitrides thereof.

16. The semiconductor structure of claim 9, wherein in the direction of the gate length, the length of the second oxygen absorbing layer (260) is greater than 80% of the length of the gate.
